(19) United States
(12) Patent Application Publication
(10) Pub. No.: US 2016/0113108 A1
(43) Pub. Date: Apr. 21, 2016

(54) PACKAGE-LEVEL ELECTROMAGNETIC INTERFERENCE SHIELDING STRUCTURES FOR A SUBSTRATE

(71) Applicant: GEORGIA TECH RESEARCH CORPORATION, Atlanta, GA (US)

(72) Inventors: Venkatesh SUNDARAM, Alpharetta, GA (US); Sung-Jin Kim, Johns Creek, GA (US); Fuhan Liu, Atlanta, GA (US); Srikrishna Sitaraman, Atlanta, GA (US); Rao R. Tummala, Greensboro, GA (US)

(73) Assignee: GEORGIA TECH RESEARCH CORPORATION, Atlanta, GA (US)

(21) Appl. No.: 14/919,685

(22) Filed: Oct. 21, 2015

Related U.S. Application Data
(60) Provisional application No. 62/066,579, filed on Oct. 21, 2014.

(51) Int. Cl. H05K 1/02; H05K 3/02; H05K 3/06; H05K 1/18; H05K 3/40

(52) U.S. Cl. CPC H05K 1/0225; H05K 1/183; H05K 3/4038; H05K 3/06; H05K 3/022; H05K 2201/032; H05K 2201/0715; H05K 2201/10083; H05K 2201/10537; H05K 2201/09209; H05K 2201/09481

(57) ABSTRACT

A electromagnetic interference shielding device is disclosed having a first substrate one or more surfaces. One or more laminates are operatively attached to the one or more surfaces of the first substrate. A cavity is provided that is defined by the first substrate and its corresponding one or more laminates and at least one inner lateral portion. The cavity is operable to receive one or more microelectromechanical system (MEMS) components. A first conductive structure integrally formed with a trench or via array of the substrate spans a thickness defined by one or more of surfaces of the first substrate, the first conductive structure operable to shield electromagnetic interference between MEMS components assembled with the first substrate.

### CROSS-REFERENCE TO RELATED APPLICATION

This Application claims benefit under 35 U.S.C §119(e) of U.S. Provisional Patent Application Ser. No. 62/066,579, filed Oct. 21, 2014, and entitled “Structure method of package-level horizontal and vertical metal patterns embedded in electronic component substrates”, which is incorporated by reference in its entirety as if fully set forth below.

### FIELD

The present disclosure generally relates to portable electronic and more specifically, substrates for use with package-level components.

### BACKGROUND

Recent consumer trends indicate that the demand for portable electronic systems continues to trend upwards. Given that the market drivers for portable electronic systems include factors such as size, performance, cost and reliability, there is often a critical tradeoff that has to be struck between cost and size of respective portable electronic systems. Because reliability may not be compromised, design considerations have focused on size and performance. Size is crucial and must be substantiated by performance while being balanced with cost. Portable electronic systems can include digital or mixed signal chips, analog chips and passives for radio frequency (RF) integration.

RF modules specifically may feature individually packaged actives and passives that are assembled on a printed wiring board. A need therefore exists for a device that is capable of being used in multiple or all regions of the world, that is multi-band and multi-mode, that is usable with high-density integration of ultra-miniaturized components in multi-band RF sub-systems. Implementing a highly-miniaturized multi-band RF sub-systems with System-On-Package (SOP), however, faces certain challenges.

Such challenges may include designing of highly integrated, embedded components for RF front end, chip package co-design of active components with embedded components, managing electromagnetic interference (EMI) between these components, as well as addressing thermal issues that arise from high-density integration.

Furthermore, ultra-miniaturized design and embedding of actives and passives have been demonstrated by previous approaches but still require improvement as to EMI and thermal management between the components. It is with respect to these and other considerations that the various embodiments described below are presented.

### SUMMARY

In some aspects, a electromagnetic interference shielding device is described having a first substrate one or more surfaces. One or more laminates are operatively attached to the one or more surfaces of the first substrate. A cavity is provided that is defined by the first substrate and its corresponding one or more laminates and at least one inner lateral portion. The cavity is operable to receive one or more microelectromechanical system (MEMS) components. These the components may include one or a combination of inductors, capacitors, and interconnections. A first conductive structure integrally formed with a trench or via array of the substrate spans a thickness defined by one or more of surfaces of the first substrate, the first conductive structure operable to shield electromagnetic interference between MEMS components assembled with the first substrate. Surfaces of the first substrate may be operable for die embedding and/or receiving one or more metallization patterns.

The substrate may be constructed from glass or otherwise be a constructed from organic, low-loss materials. The cavity may also be metalized or coated such that the cavity may be partially or completely filled with conductive or non-conductive material

In certain embodiments, the first conductive structure may be integrally formed with the trench of the substrate. In this embodiment, the first conductive structure may provide up to 25 dB more lateral isolation than via-arrays. However, the device is not so limited and the first conductive structure may instead be integrally formed with a continuous pad of a via array of the substrate, the continuous pad being disposed at a predetermined height relative to the substrate (e.g. 20-40 μm). One or more surfaces of the first conductive structure may be generally orthogonal to the first substrate and extend a predetermined height relative to the substrate.

In other embodiments, the cavity may be partially or completely filled with conductive or non-conductive material. The first conductive structure may also include a plurality of individual portions separated and arranged in a predetermined pattern or array as needed or required. One or more planar surfaces of the first conductive structure may be operable to surround or form a dividing EMI shield between one or more MEMS components in communication or otherwise assembled with the first substrate. The individual portions may in turn shield the MEMS components from interfering with each other and from interfering with signal lines inside and outside a system-on-package corresponding with the device.

A second conductive structure may be provided and oriented parallel with the substrate in a manner that covers the cavity. The first and second conductive structures may be constructed, partially or completely, from of a conducting magnetic material. However, the first and/or second conductive structures are not so limited and instead may be constructed from a multi-layer structure. The multi-layer structure may include a magnetic layer positioned between a non-magnetic layer and an insulator layer and each layer may be from the same metal or may be from different metals as described more particularly below.

In some embodiments, the one or more MEMS components may be electrically connected to the one or more surfaces of the first substrate in a face-down orientation. In this respect, the one or more MEMS components may be electrically connected to one or more terminals of a system-on-package package corresponding with the device.

A second substrate may also be used with the first substrate. having one or more surfaces, the second substrate being similar to the foregoing first substrate and disposed above of the first substrate and including a conductive structure that functions as an EMI shield for one or more MEMS components assembled therewith. The first and second substrates may be electrically connected and their conductive structures may also be constructed from one, or a combination of, Cu, CoZr, and Al.

In other embodiments, an electromagnetic interference trench-based shielding system is disclosed having a substrate having one or more surfaces. The substrate may be operable to receive one or more microelectromechanical system (MEMS) components. A first conductive structure may span a thickness defined by one or more of surfaces of the substrate and may extend outwardly from the substrate to a predetermined height relative substrate. The first conductive structure may be in communication with a trench of the substrate and oriented generally orthogonal to the first substrate. In this respect, the first conductive structure may be integrally formed with the trench or otherwise assembled, connected, attached, or formed therewith. The first conductive structure separates at least two MEMS components assembled to the substrate.

A process of fabricating one or more electromagnetic shields between components for ultra-thin radiofrequency packages is also disclosed herein. The process may include the following steps: selectively inserting one or more through package vias (TPVs) in a substrate; removing residue from an edge of the one or more TPVs by desmearing; electroless seed plating the substrate thereby increasing thickness and conductivity; coating the substrate by electrolytic plating with a metal; thinning upper and lower surfaces of the substrate; laminating upper and lower surfaces of the substrate with a first layer of photoresist film; exposing the first layer of photoresist film of the upper and lower surfaces to wavelengths in the ultraviolet spectrum; subtractive etching the electrolytic plating on the upper and lower surfaces of the substrate and stripping the photoresist film; electroless seed layer plating on the upper and lower surfaces of the substrate; applying a relatively a second layer of photoresist film to the upper surface of the substrate, the second layer being thicker than the first layer of photoresist film; exposing the second layer of photoresist film to wavelengths in the ultraviolet spectrum; electroplating the second layer of photoresist film with a metal; stripping the relatively thick photoresist film and etching the electroless seed layer on the upper surface of the substrate thereby forming one or more electromagnetic interference (EMI) shields in communication with corresponding trenches of the substrate; and laminating one or more layers to apply uniform pressure to uneven profiles of the substrate caused by the one or more EMI shields.

The TPVs may be selectively inserted using laser ablation through use of UV, excimer, CO₂, or CO₂T lasers. However, the process is not so limited and other forms of TPV insertion are contemplated including mechanical, photo-definable where the material is photo sensitive and patternable by selective exposure to light. Chemical forms of removal may also be used where, for example, in the photo-definable process, a chemical may be used as a “developer” to remove the uncured patterns.

The substrate may also be electroless seed plated with copper. In certain embodiments, thinning of the upper and lower surfaces of the substrate may be carried out by chemical etching. Desmearing may be accomplished through plasma, chemical desmear, or through use of lasers. Other aspects and features of the present disclosure will become apparent to those of ordinary skill in the art, upon reviewing the following detailed description in conjunction with the accompanying figures.

### BRIEF DESCRIPTION OF THE DRAWINGS

Reference will now be made to the accompanying drawings, which are not necessarily drawn to scale.

FIG. 1 depicts a perspective view of exemplary dies positioned adjacent each other and being shielded using an exemplary conductive structures.

FIG. 2 depicts a perspective view of other exemplary dies positioned adjacent each other and being shielded using another exemplary conductive structure.

FIG. 3 depicts a perspective view of exemplary dies positioned adjacent each other similar to FIG. 1, wherein the dies are being shielded using an exemplary conductive structures and are housed underneath a second conductive structure.

FIG. 4 depicts a lower perspective view of exemplary dies assembled with an Conductive structure.

FIG. 5 depicts a side plan view of an exemplary substrate in use with the herein disclosed Conductive structures and MEMS components.

FIG. 6a depicts a side plan view of an conductive structure when constructed from a novel multi-layer material layup.

FIG. 6b depicts a side plan view of an exemplary schematic of an incoming wave confronted with an exemplary material stack-up of FIG. 6a.

FIG. 7a depicts a schematic overview of a fabrication process for a substrate with conductive structures.

FIG. 7b depicts a side plan view of an exemplary substrate and corresponding conductive structures upon completion of the process of FIG. 7a.

FIG. 8a depicts a schematic overview of a fabrication process for a substrate with conductive structures.

FIG. 8b depicts a side plan view of an exemplary substrate and corresponding conductive structures upon completion of the process of FIG. 8a.

FIG. 9 depicts a schematic overview of another fabrication process for a substrate with conductive structures.

FIG. 10 depicts a top view of the simulation set-up for testing summarized in FIGS. 11-15.

FIG. 11 depicts a top plan view of an exemplary simulation setup for one embodiment of the herein disclosed substrate and corresponding shield as graphically depicted in FIGS. 12-15.

FIG. 12 depicts test results graphically comparing shielding effectiveness of different materials in use with an exemplary shielding structure.

FIG. 13 depicts test results graphically comparing shielding effectiveness with varying thicknesses of a shield material.

FIG. 14 depicts test results graphically comparing of transmission line-to-transmission line coupling in the presence of either via arrays or trenches.

FIG. 15 depicts test results graphically comparing of transmission line-to-transmission line coupling in the presence of either via arrays or trenches after the herein disclosed substrate has been fabricated.

FIG. 16a depicts an upper perspective view of testing conditions of the continuous, via-array embodiments of FIG. 15.

FIG. 16b depicts an upper perspective view of testing conditions of the discrete, via-array embodiments of FIG. 15.

FIG. 17a depicts a side plan view of testing conditions of the continuous, via-array embodiments of FIG. 15.

FIG. 17b depicts a side plan view of testing conditions of the discrete, via-array embodiments of FIG. 15.

### DETAILED DESCRIPTION

The subject matter of the various embodiments is described with specificity to meet statutory requirements. However, the description itself is not intended to limit the scope of the claimed invention. Rather, it has been contemplated that the claimed invention can be embodied in other ways, to include different steps or elements similar to the ones described in this document, in conjunction with other present or future technologies. Although the term “step” can be used herein to connote different aspects of methods employed, the term should not be interpreted as implying any particular order among or between various steps herein disclosed unless and except when the order of individual steps is explicitly required. The following description is illustrative and non-limiting to any one aspect.

It should also be noted that, as used in the specification and the claims, the singular forms “a,” “an” and “the” include plural references unless the context clearly dictates otherwise. For example, reference to a component is intended to also include composition of a plurality of components. References to a composition containing “a” constituent are intended to include other constituents in addition to the one named. Also, in describing preferred embodiments, terminology will be resorted to for the sake of clarity. It is intended that each term contemplates its broadest meaning as understood by those skilled in the art and includes all technical equivalents that operate in a similar manner to accomplish a similar purpose.

Ranges can be expressed herein as from “about” or “approximately” one particular value and/or to “about” or “approximately” another particular value. When such a range is expressed, other exemplary embodiments include from the one particular value and/or to the other particular value. The terms “comprising” or “containing” or “including” mean that at least the named component, element, particle, or method step is present in the system or article or method, but does not exclude the presence of other components, materials, particles, or method steps, even if the other such components, material, particles, and method steps have the same function as what is named.

It is also to be understood that the mention of one or more method steps does not preclude the presence of additional method steps or intervening method steps between those steps expressly identified. Similarly, it is also to be understood that the mention of one or more components in a system or composition does not preclude the presence of additional components than those expressly identified. To facilitate an understanding of the principles and features of the present invention, embodiments are explained hereinafter with reference to implementation in illustrative embodiments.

As discussed herein, a “highly miniaturized” may signify components with a distance of separation between other components in a device or system ranging from 0.1-3 mm.

In the following description, references are made to the accompanying drawings that form a part hereof and that show, by way of illustration, specific embodiments or examples. In certain embodiments of the present disclosure, the herein disclosed system 100 is operable to achieve ultra-miniaturized EM shield integration without compromising on the size and/or form factor while still mitigating the EMI of system 100 between components therein. Components of system 100 may include passive components including inductors and capacitors as well as interconnections such as vias, transmission lines and chip bumps. The dimensions of these elements may be dependent on necessity and design of the particular package associated with system 100.

Regarding EMI in particular, unlike electric fields, low wave-impedance of magnetic fields in the near-field region makes it difficult to shield magnetic waves through reflection loss. A shield with high absorption loss is typically used to address EMI issues which can be achieved through shields with large thickness, high conductivity, or high permeability. However, in ultra-miniaturized systems, the metal thickness cannot be high enough which results in low absorption loss. In addition, magnetic materials tend to exhibit high permeability only up to a particular frequency such that present shields have shortcomings in terms of design limitations related to thickness and materials.

Additionally, with increasing miniaturization in packaging, the demand for miniaturized shields offering equal or better isolation is crucial. Certain approaches have included incorporating a cage structure to isolate RF and digital signals. This particular approach has been used with stacked packages. However, this approach fails to provide sufficient isolation and is a frequency-dependent solution.

Other approaches have incorporated metal can structures for EMI shielding and isolation for the board at the system level around different sub-sections. However, this approach suffers from being too bulky, heavy and for failing to provide shielding from internal interference. Other approaches have also included integrated, over-molded shields for isolating Tx and Rx circuits at the sub-package level. This integrated, over-molded solution, however, suffers by providing insufficient isolation due to holes in its shield. Therefore, problems in the art remain unresolved as to shielding between densely packed components in a miniaturized packages at least because of the complexities resulting from miniaturization of the shields.

System 100 as described herein solves these and other problems of the art by effectively shielding respective components from EM radiation with no resonance due to aperture. System 100 may also eliminate the need for a bulky metal enclosure on the printed circuit board (PCB) formed therewith. In this respect, system 100 as described more particularly below may permit use of high proximity of digital and RF components with correspondingly low costs, a relatively compact form-factor, and improved thermal relief for system 100.

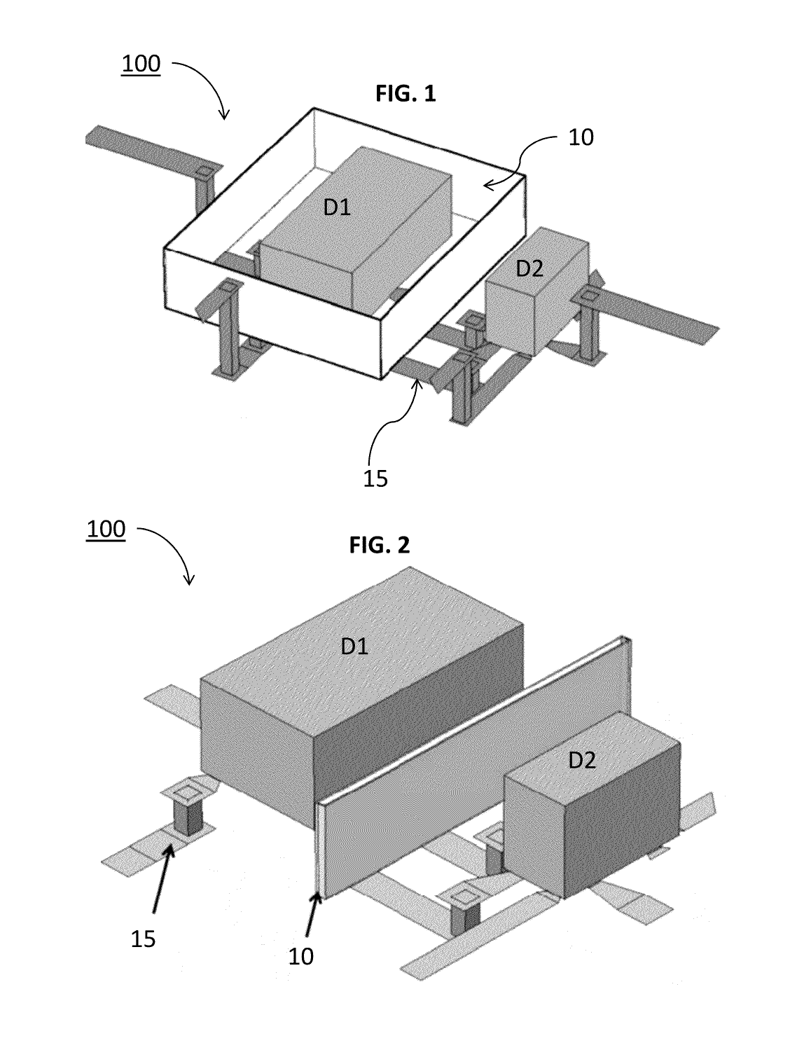

Specifically, system 100 may be capable of providing between 30-60 dB EM isolation at distances less than 100 a frequency range of 1-20 GHz, and thickness of shield material less than 10 μm. System 100 as depicted in FIG. 1 may include novel conductive structures 10 generally planar and/or orthogonal relative to other components adjacent therewith including substrate 3 and/or any corresponding surfaces of components such as dies D1, D2 or interconnections 15. As can be seen, structure 10 of FIG. 1 may substantially surround die 1 across one or more multiple edges of die 1. As can also be seen, one or multiple surfaces of structure 10 may operatively divide each of dies 1 and 2 and shield EMI therebetween. Structures 10 may shield components such as dies D1 and D2 from interference caused by other components and signal lines inside and outside the package. Structures 10 may therefore be optimized depending on material, distance from radiation source, and geometry. In some embodiments, structures 10 can be used in designing relatively high-quality, high-density embedded passives, heat dissipation entities and/or antenna structures. In this respect, structures 10 of FIG. 1 may be positioned in communication with respective interconnections 15 and dies 1 and 2 and may regulate thermal conditions by removing and/or regulating heat generated by dies 1 and 2. In this respect, interconnections 15 can be seen being operatively connected to external components onto which heat may be dissipated from structures 10.

Turning to FIG. 2, instead of substantially surrounding die 1 as in FIG. 1, structure 10 may instead simply run parallel between dies D1 and D2 and operatively shield EMI much as in FIG. 1. As can be seen in both FIGS. 1 and 2, structure 10 may include a predetermined height and thickness depending on need or design. An upper, distal portion of structure 10 may be co-planar with either or both of the upper surfaces of dies D1 and D2, may extend below, or may extend above the upper surfaces of dies D1 and D2.

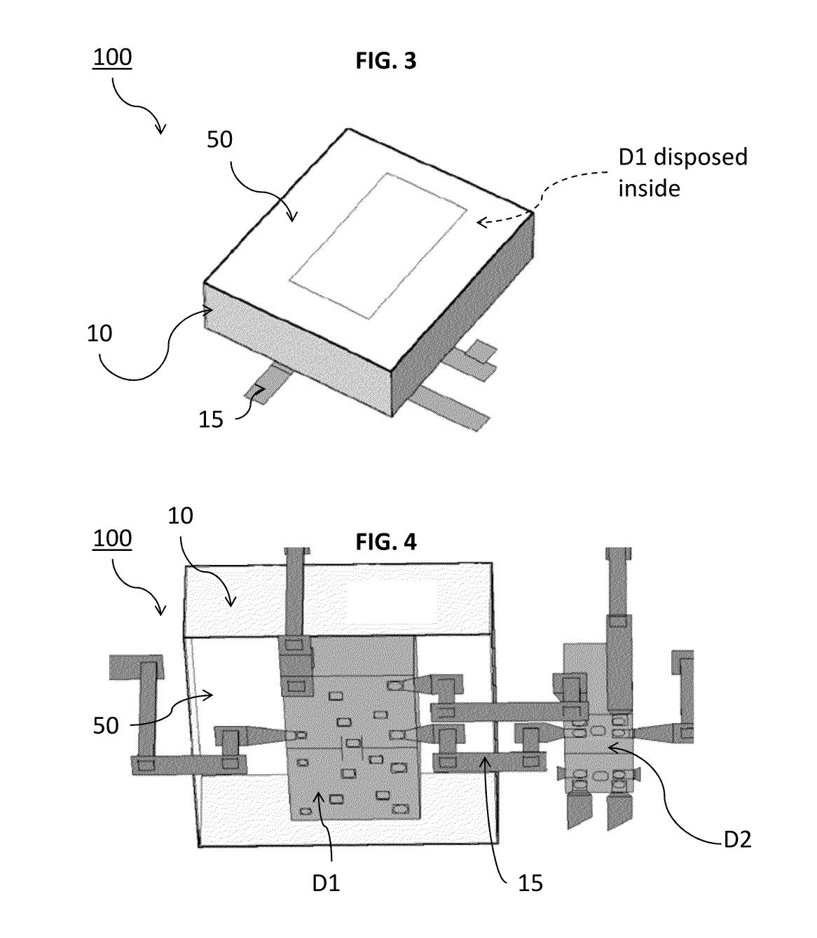

Turning to FIG. 3, another embodiment of structure 10 and corresponding components of system 100 are depicted, wherein structure 10 can be seen surrounding die D1. However, an additional conductive structure 50 may be operatively attached, formed, or otherwise connected to the upper portion of structure 10 so that die D1 is essentially sealed or housed by the cavity formed between structures 10 and 50. This is more clearly seen in FIG. 4, wherein structure 10 can be seen generally surrounding die D1 while structure 50 is situated adjacent or in communication with the upper, distal portion of die D1. Advantageously, structures 10 and/or 50 provide increased isolation as between adjacent dies D1 and D2, enable greater miniaturization, and provide for relatively simpler routing.

As can be seen in FIGS. 1-4, dies D1 and D2 may preferably be positioned adjacent each other instead of being positioned one under the other. Dies D1 and D2 may be arranged in this manner to avoid issues of ground proximity, having to share a common ground, and/or having to provide an extra layer for a dedicated ground plane. Instead, structures 10 of system 100 in FIGS. 1-5 advantageously increase isolation despite the fact that miniaturization may be higher. Additionally, structures 10 when arranged with adjacent dies D1 and D2 of FIGS. 1-4 provides for relatively simpler routing versus if dies D1 and D2 were positioned one under the other.

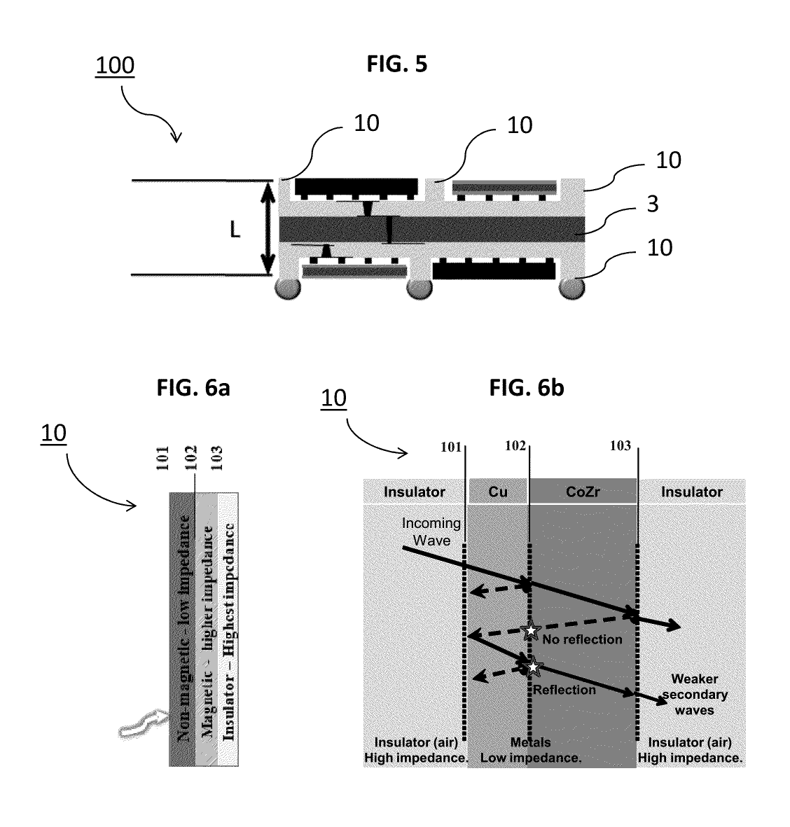

Turning to FIG. 5, system 100 is depicted with exemplary substrate 3 integrally formed with multiple structures 10 and components assembled thereon. As can be seen, substrate 3 may be used in semiconductor package circuits such as system 100 by providing a mechanical base support and an electrical interface for external communication access to the components such as dies D1 and D2 that may be assembled thereon. Substrate 3 may be constructed from one or more plastics and/or metals such as copper, nickel, aluminum, nickel-iron (NiFe), and cobalt-zirconium (CoZr). In a preferred embodiment, substrate 3 may be ultra-thin and have relatively low electrical loss with exceptional dimensional stability.

Substrate 3 of FIG. 5 may range between 30 μm and 100μ. However, substrate 3 is not so limited and any material and material thickness may be used as needed or required. Structures 10 of FIG. 5 may be formed with trenches and/or via arrays of substrate 3, continuous or discrete, and these trenches and/or via arrays may be metalized and/or formed in its build-up layers. It is to be understood that a via can include a small opening in an insulating layer of substrate 3, the via being operable to permit a conductive connection between different layers of substrate 3. Similarly, system 100 once fabricated with necessary laminates, substrate, and structures 10 may range between distance between length L of 0.1 and 0.25 mm. However, length L of any of the herein described systems 100 may vary according to need or preference.

Components of system 100 such as dies D1 and D2 of FIGS. 1-4 may be assembled with structures 10. In turn, dies D1 and D2 may be separated by approximately 50 μm in interconnect length. Structures 10 may be embedded and surface-assembled with ultra-thin actives and passives and may be used with ultra short interconnections 15 with high current handling as described more particularly below.

Turning to FIG. 6a, a novel, multi-layer material stack-up 10 is described that may be used with system 100 for combination of magnetic, non-magnetic and insulating thin-films. In this embodiment, as conductivity increases, the shield impedance of the structures 10 of system 100 may decrease and as the permeability increases, the shield impedance also increases. As more clearly seen in FIG. 6b, when an incoming, exemplary near-field magnetic wave impinges the shield of structure 10 at non-magnetic layer 101, this wave gets attenuated due to absorption loss in layer 101. Since magnetic fields get reflected only when propagating from a low-impedance medium into a high-impedance medium, this wave gets reflected only at layer 102. Upon reflection, a part of the wave continues to propagate further inside the shield defined by structure 10 and undergoes a reflection between layers 102 and 103. Advantageously, stack 110 minimizes the effect of multiple reflections and an outgoing magnetic field wave is reflected out of layer 103.

This outgoing wave does not get reflected at layer 102 since the impedance of the insulator layer 102 is higher than that of the magnetic layer 103. Instead, the outgoing wave reflected from layer 103 experiences the first reflection only at layer 101 as it propagates from layer 101 into the air medium outside the associated shield. Thus, layer 101 helps eliminate the effect of multiple reflections in layer 102. Further, the part of the wave that gets reflected inside at layer 101 tries to enter the shield again but the wave is reflected at layer 102 and then at layer 103 while also being absorbed in layers 101 and 102. Accordingly, reflected waves that re-enter the shield of structure 10 that could otherwise manifest as secondary and tertiary emissions out of structure 10 are instead attenuated by a series of absorption and reflection losses.

While the most effective and stable material choice in those embodiments that use multi-layer structure 10 of FIG. 6a is Cu due to its frequency limitations and compatibility with standard substrate fabrication processes, structure 10 is not so limited. As seen in FIG. 6b, structure 10 may also use a combination of materials for shielding in 1-3 GHz frequency band as well as shielding of up to 20 GHz. As seen more clearly in FIG. 6b, structure 10 may be constructed from layers of 200 nm of Cu as layer 101, 200 nm CoZr as layer 102, and 20 nm Al as layer 103.

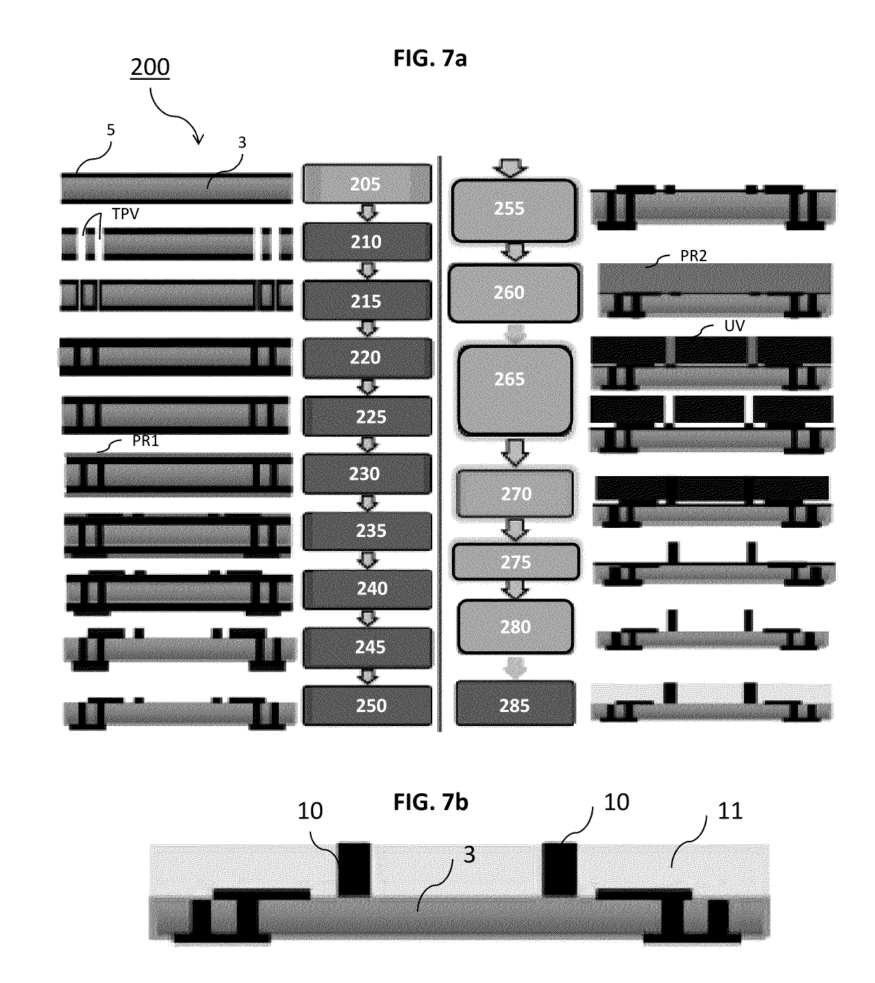

Turning to FIGS. 7-9, exemplary processes 200, 300, 400 for fabrication of system 100 and corresponding structures 10 with substrates 3 are depicted, each of processes 200, 300, 400 being operable to aid in resolving related to cavity formation using laminates, such as high flow prepreg. Additionally, because of relatively high thicknesses in certain instances of the herein described structures 10 of system 100, use of metallic paste may be used to expedite processes 200, 300, 400. In this respect, the metallic paste may be derived from copper or silver particles that are infused in an organic medium.

Turning to FIG. 7a, a method 200 of fabricating system 100 with corresponding structures 10 is disclosed, wherein a core laminate such as glass may be provided forming substrate 3 in step 205. Moving to step 210, one or more TPVs may be positioned in substrate 3 via laser ablation or any other manner as needed or desired. After insertion of the TPVs, any residue that remains at the edge or periphery of each TPV may then be removed by a desmearing process (e.g. through a plasma treatment) in step 215. Substrate 3 may also undergo electroless copper seed plating of substrate 3 as depicted in step 215 to increase thickness and/or improve conductivity of system 100. However, the step 215 is not so limited and other materials are contemplated for use in electroless seed plating including nickel, silver, and gold.

Substrate 3 may then undergo electrolytic plating in step 220 to further coat the substrate 3 with one or more layers of a metal such as gold, silver, tin, zinc, copper, cadmium, chromium, nickel, platinum, lead, or the like. Upper and/or lower surfaces of substrate 3 may then be thinned down in step 225 and then undergo photoresist (PR) lamination 230 on the lower and/or upper surfaces. Preferably, PR film layer of step 230 may be relatively thin and may be applied on both the lower and upper surfaces by, for example, a laminating mechanism. Layers of step 230 may also be any positive and/or negative photoresists capable of being used with substrates constructed from materials such as Si, GaAs, InP, glass, or metals such as Au, Cu and Al. Thereafter, the one or more PR film layers laminated with substrate 3 may be exposed in step 235 to wavelengths in the ultraviolet spectrum (e.g. less than 400 nm).

However, step 235 may also include exposing the one or more PR film layers of step 230 to an electron beam. Patterning and/or metallization of the core metal layers and the TPVs of steps 205 to 235 may be performed using double-side wet metallization techniques. In addition, shielding trenches and/or TPVs of substrate 3 may be simultaneously formed thereon using laser ablation, mechanical removal, or chemical removal. In those embodiments where laser ablation is used, UV, excimer, CO₂, and CO₂T lasers may be used depending need or preference.

In step 240, the core of system 100 may then be developed with build up and then undergo subtractive etching 245. The PR film layers of 230 may then be stripped therefrom in step 250. Thereafter, system 100 may undergo electroless metal layer plating and preferably, copper seed layer plating in step 255. System 100 may then receive a relatively thick layer of photoresist film 260 and again, expose system to wavelengths in the ultraviolet spectrum and further develop system 100 in step 265. System 100 may then undergo electroplating with a metal such as copper 270 to form structures 10, have its PR film layer stripped therefrom 275, and undergo seed layer etching 280. Finally, system 100 in step 285 may undergo further build-up lamination by, for example, adding an additional layer to apply uniform pressure resulting from uneven profiles caused by structures 10. Carrying out the foregoing steps of process 200 leaves system 100 fully formed with corresponding structures 10 ready for EMI shielding between components of system 100. Further processing of any of the previously described steps of process 200 may be repeated as needed or required. FIG. 7b in turn depicts a side plan view of the system 100 as fabricated by process 200.

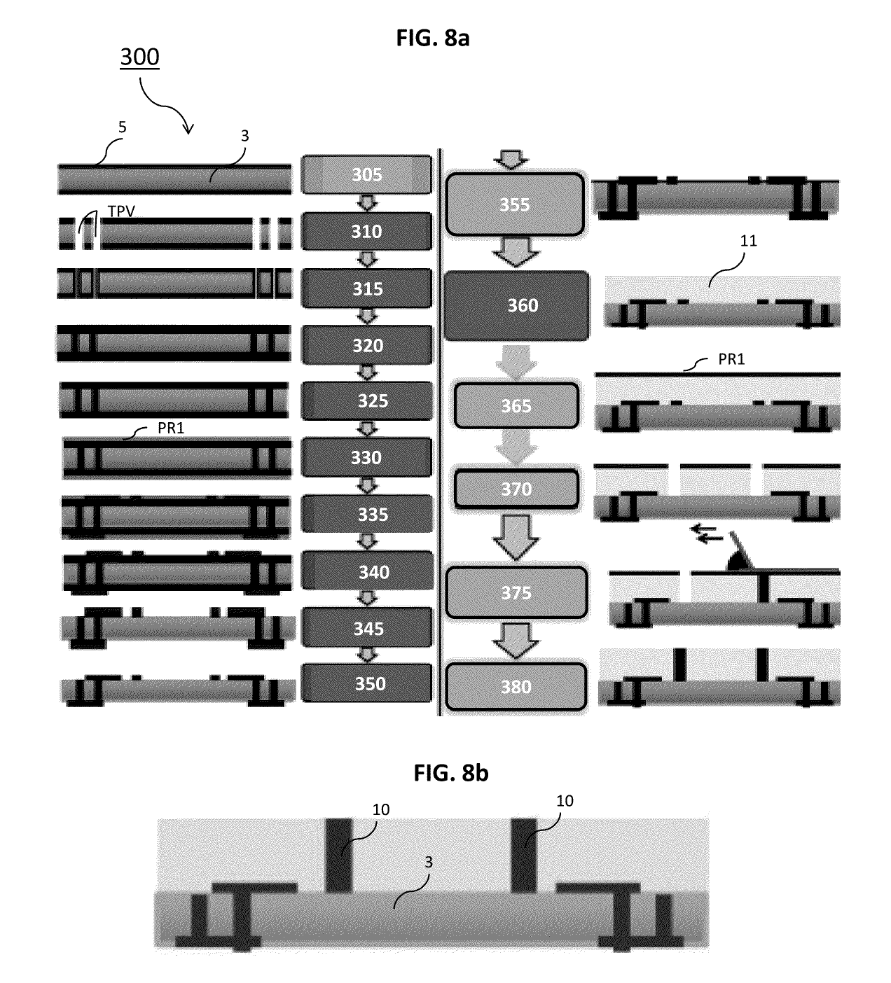

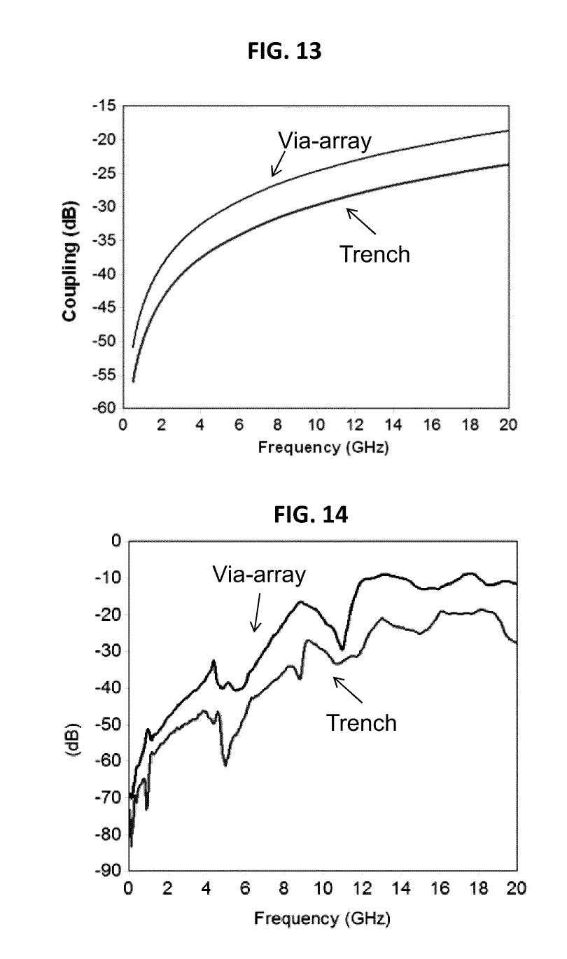

Turning to FIG. 13, a process 300 of fabrication similar to process 200 is depicted, process 300 differing from process 200 after steps 355, 255. Specifically, step 360 may include system 100 undergoing build-up lamination by, for example, adding an additional layer to apply uniform pressure resulting from uneven profiles of the core. System 100 may then be laminated with PR film layers 365 so that one or more cavities are formed 370 between the substrate 3 core and the PR film, wherein the PR film of step 365 may be relatively thin. In step 375, a laminating tool such as a squeegee may be manipulated to evenly distribute a conductive paste in the cavity of step 370 to form structures 10. Finally, the PR film layer may be stripped 375 leaving system 100 with corresponding, trench-based structures 10. Further processing of any of the previously described steps of process 300 may be repeated as needed or required. FIG. 8b in turn depicts a side plan view of the system 100 as fabricated by process 300.

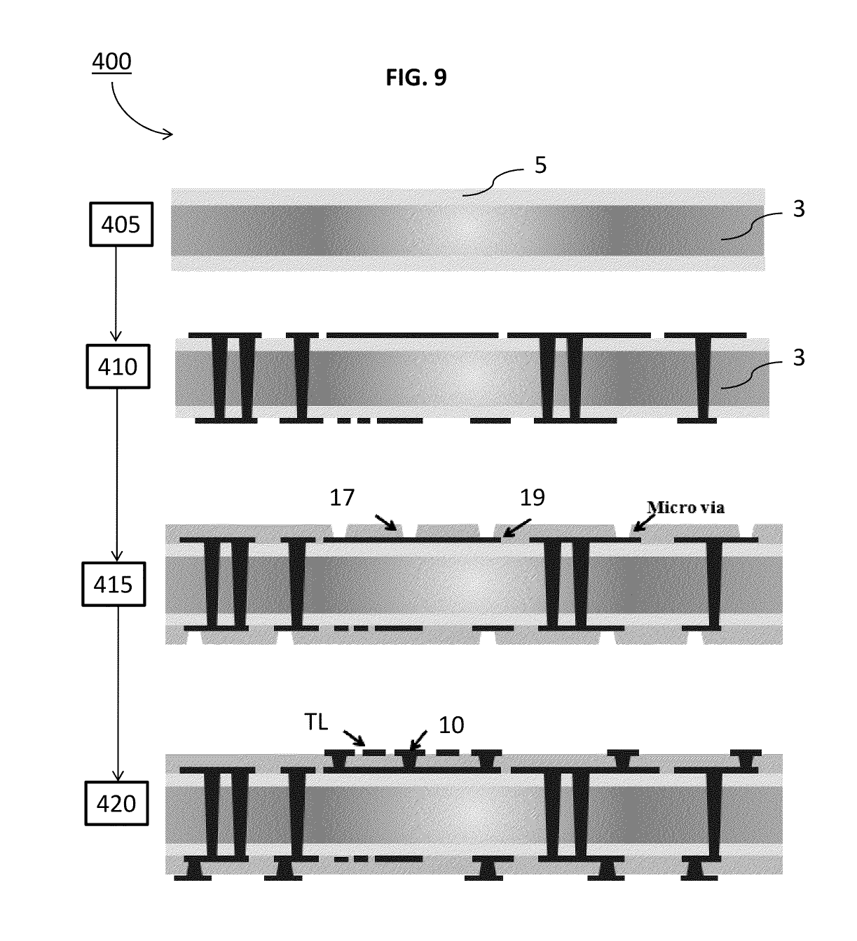

Turning to FIG. 9 is another exemplary process 400 of fabricating system 100. Specifically, process 400 as depicted is capable of combining the herein described system 100 with a standard substrate fabrication processes without necessarily increasing the process steps. The first step 405 may include cleaning substrate 3 followed by polymer lamination of laminate 5 on both sides of substrate 3. In an exemplary embodiment, step 405 may include laminating the polymer on 100 μm glass. TPVs may then be formed in step 410 using laser ablation or the like. Step 410 may also include a double-side wet metallization process such that the core of laminate 5, substrate 3, and TPVs may be metalized (e.g. with copper) and then patterned. Step 415 of process 400 may then include build-up polymer lamination on both sides of substrate 3. The shielding trenches 17 are then formed with ground planes 19 and the micro vias may then be simultaneously formed on the build-up through any number of techniques including laser ablation with an ultraviolet laser. Finally, the metallization of the trenches 17 along with the metallization of the micro via may be carried out in step 420 to form structures 10.

### Testing

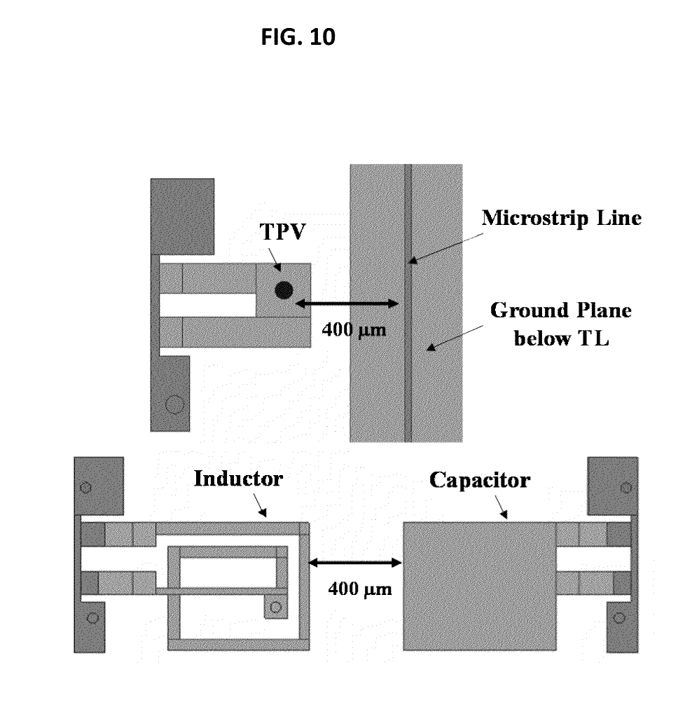

Examples of certain implementations of the disclosed system 100 will now be described with respect to FIGS. 10-17. Specifically, in order to study the coupling between package elements with exemplary structures 10, simulations were performed using an HFSS—a full-wave 3D EM tool with a TPV, a capacitor, an inductor and a transmission line (TL) is shown in FIG. 10. To study the coupling, these elements were integrated into a simulation and the signal coupling was studied, assuming 400 microns of separation therebetween. The solution set-up type was “driven-terminal”, and lumped ports were employed to excite structures 10 as well as to study the induced interference. The simulation was performed from 100 MHz to 20 GHz, in steps of 100 MHz.

The substrate analyzed in this example was constructed from compatible metals including copper, nickel, aluminum, nickel-iron (NiFe), and cobalt-zirconium (CoZr). Above each material's ferro-magnetic resonance frequency, it is understood that magnetic materials tend to absorb radiation incident thereon. Pursuant to each material analyzed, the ferromagnetic resonance (FMR) was determined through experimental characterization as follows:

| | Resistivity | | | |
|---|---|---|---|---|
| Material | (μ ohm cm) | Permeability | FMR | |
| Copper | 1.68 | 1 | — | |
| Aluminum | 2.8 | 1 | — | |
| Nickel | 6.99 | 100 | 20 | MHz |
| CoZr | 100 | 200 | 3 | GHz |
| NiFe | 50 | 400 | 1 | GHz |

Analytical calculations were performed to estimate the shield effectiveness of the above-listed materials assuming a distance between source and shield of approximately 0.5 mm. The simulation considered a frequency range of 0.5 GHz-20 GHz since this covers the operating frequencies of WLAN and cellular RF modules, including three harmonics. The impact of thickness on shield effectiveness was also studied by varying the metal thickness from 1-5 μm.

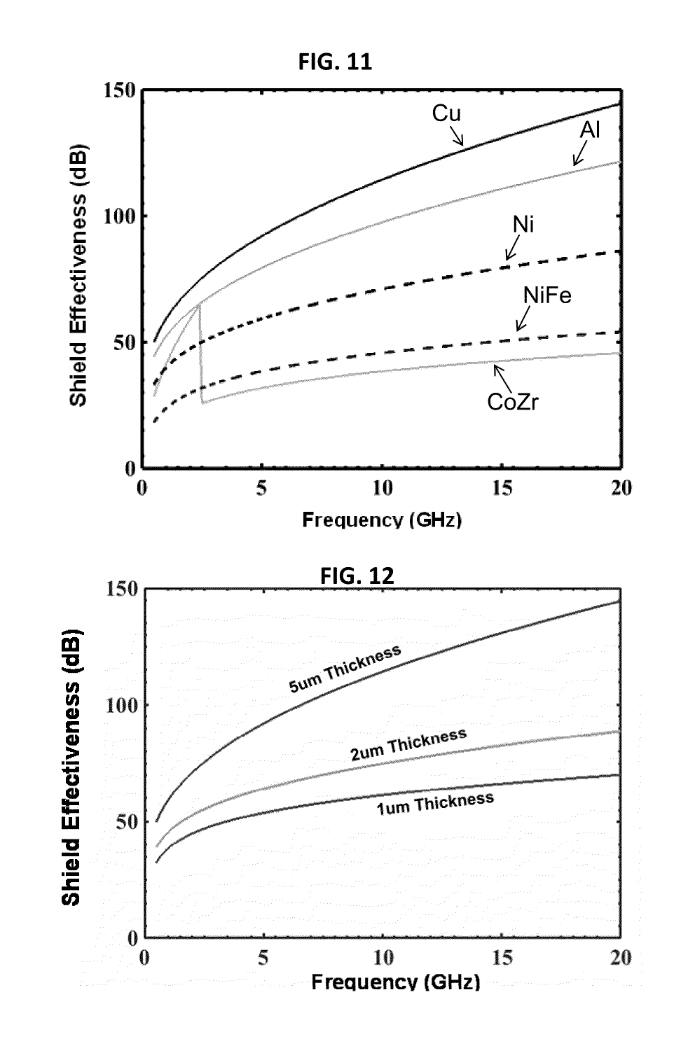

In FIG. 11, the comparison of shield effectiveness between the different materials is shown. It can be observed that Cu and Al have the best shield effectiveness because of their low resistivity whereas nickel and nickel-iron demonstrated low shield effectiveness. Regarding Ni and NiFe, this is likely attributed to the fact that the frequency ranges analyzed were already past the FMR of nickel and nickel-iron. Since shielding due to FMR is not captured in FIG. 11, the actual shielding effectiveness can be expected to be higher for Ni, NiFe and CoZr. Additionally, the effect of metal thickness on shield effectiveness for Cu is depicted in FIG. 12, wherein shield effectiveness can be seen increasing with respective thickness since the dominant shielding phenomenon at these frequencies is absorption loss which depends on the thickness of the metal used with structure 10.

Turning to FIG. 13, the shielding effectiveness via array was also evaluated as between trenches and via arrays when used with structures 10 as well as with TLs with substrate 3 through full-wave EM simulations with a full-wave EM simulator. Parameters of structure 10 ranged as follows:

| Parameter | Dimension |
|---|---|
| Micro-Via diameter, Trench | 45 μm |
| diameter | |
| Metal thickness | 6 μm |
| Dielectric thickness | 15 μm |

To study the shield effectiveness, a pair of microstrip transmission lines of length 15 mm, separated by 180 microns, were considered and the required shield structure was integrated between them. The far-end crosstalk between these lines was employed to compare the shield effectiveness of the shield structures. The simulations of the via array and trench were performed and the comparison of their shield effectiveness revealed that the shield effectiveness of the trench structure was more than that of the via array, with the highest simulated EM isolation between the transmission lines being 20 dB for the trench and 25 dB for the via array.

With respect to FIG. 14, after fabrication of system 100, 50-Ohm SMD resistors were assembled on the coupons to terminate the TLs. Following this, RF characterization using GSG RF probes was carried out using a vector network analyzer. To measure EMI between the lines, two-port S-parameter characterization was performed and measurements showed reasonable correlation with the simulations, with the trench structures offering up to 20 dB increased isolation between components, compared to via-array shields.

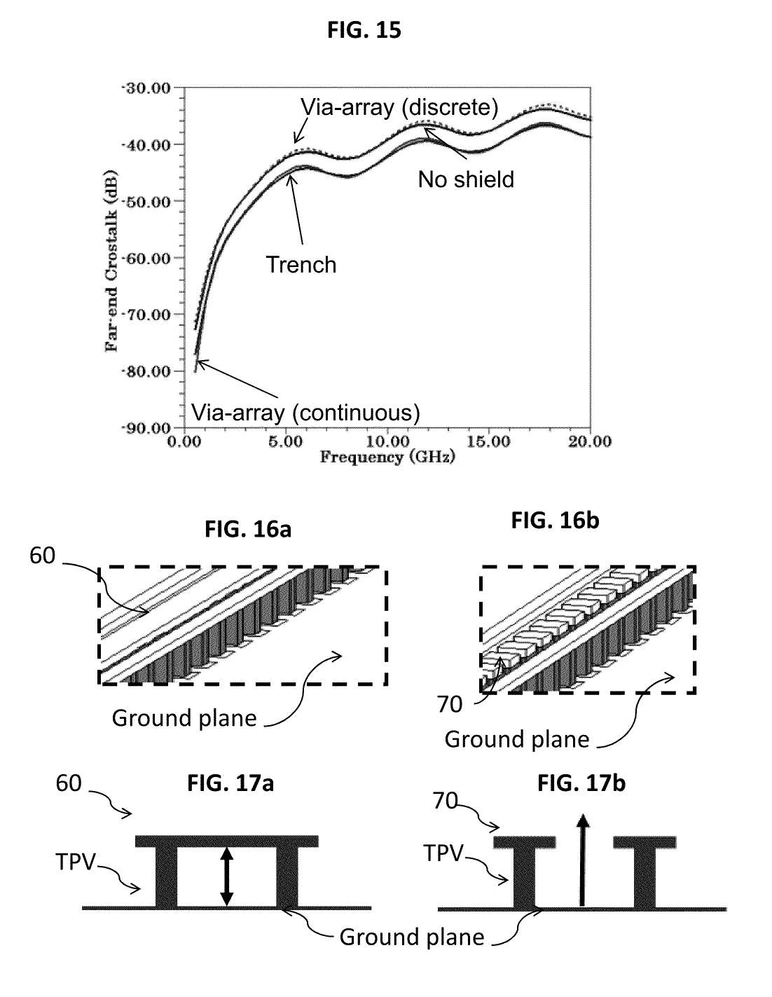

Finally, in FIG. 15, TL-TL coupling was evaluated as between via arrays with discrete pads and continuous pads as compared with trench-based structures versus no shielding at all. Testing conditions are graphically depicted in FIGS. 16 through 17, FIGS. 16a and 17a corresponding to testing conditions where via arrays are coupled with continuous pads whereas FIGS. 16b and 17b correspond to testing conditions with arrays coupled with discrete pads. Continuous pads 60 can be clearly seen on the upper metal layer in FIGS. 16a and 17a being merged and it was observed that the shielding effectiveness matched that of trench-based shields. FIG. 15 further reveals that discrete pads 70 may not reduce the coupling between the TLs. In contrast, pads 60 improved efficacy of shielding insofar as being similar to the trench-based shield that was tested. As can be seen in the side plan views of FIGS. 17A and 17B depicting via-array shields with pads 60 and 70, pad 60 and its aperture is bound whereas the aperture of discrete pad 70 is unbound. With pad 70, only very high frequencies are capable of propagating whereas with pad 60, frequencies that range between 1-20 GHz may propagate.

The presence of trench-based structures 10 were also used with said trench being positioned above the plane of associated transmission lines between 20 μm and 40 μm. When the trenches were extended vertically upwards by 20-40 μm, the shield effectiveness was observed to increase by up to 6 dB.

### Conclusion

The specific configurations, choice of materials and the size and shape of various elements can be varied according to particular design specifications or constraints requiring a system or method constructed according to the principles of the disclosed technology. Such changes are intended to be embraced within the scope of the disclosed technology. The presently disclosed embodiments, therefore, are considered in all respects to be illustrative and not restrictive. The scope of the disclosure is indicated by the appended claims, rather than the foregoing description, and all changes that come within the meaning and range of equivalents thereof are intended to be embraced therein.

What is claimed is:

1. An electromagnetic interference shielding device, comprising:
a first substrate having one or more surfaces;
one or more laminates operatively attached to the one or more surfaces of the first substrate;
a cavity defined by the first substrate and corresponding one or more laminates and at least one inner lateral portion, the cavity being operable to receive one or more microelectromechanical system (MEMS) components; and
a first conductive structure spanning a thickness defined by one or more of surfaces of the first substrate, the first conductive structure operable to shield electromagnetic interference between MEMS components assembled with the first substrate.

2. The device of claim 1, wherein surfaces of the first substrate are operable for die embedding or receiving one or more metallization patterns.

3. The device of claim 1, wherein the first conductive structure is integrally formed with a trench of the substrate.

4. The device of claim 1, wherein the first conductive structure is integrally formed with a continuous pad of a via array of the substrate, the continuous pad being disposed at a predetermined height relative to the substrate.

5. The device of claim 3, wherein the first conductive structure comprises one or more planar surfaces generally orthogonal to the first substrate and extends a predetermined height relative to the substrate.

6. The device of claim 1, wherein the cavity is partially or completely filled with conductive or non-conductive material.

7. The device of claim 5, wherein the first conductive structure comprises a plurality of individual portions separated and arranged in a predetermined pattern.

8. The device of claim 5, wherein one or more planar surfaces of the first conductive structure surround or form a dividing shield between the one or more MEMS components in communication with the first substrate.

9. The device of claim 5, wherein the individual portions of the first conductive structure shield the MEMS components from interfering with each other and from interfering with signal lines inside and outside a system-on-package corresponding with the device.

10. The device of claim 5, further comprising: a second conductive structure oriented parallel with the substrate and covering the cavity.

11. The device of claim 10, wherein the first and second conductive structures are constructed partially or completely from of a conducting magnetic material.

12. The device of claim 1, further comprising: the one or more MEMS components electrically connected to the one or more surfaces of the first substrate in a face-down orientation.

13. The device of claim 12, wherein the one or more MEMS components are electrically connected to one or more terminals of a system-on-package package corresponding with the device.

14. The device of claim 12, further comprising:
a second substrate having one or more surfaces, the second substrate being disposed above of the first substrate;
one or more laminates operatively attached to the one or more surfaces of the second substrate;
a cavity defined by the second substrate and one or more corresponding laminates and at least one inner lateral portion, the cavity of the second substrate being operable to receive one or more microelectromechanical system (MEMS) components;
a first conductive structure spanning a thickness defined by one or more of surfaces of the second substrate and extending outward from the second substrate a predetermined distance, the first conductive structure being integrally formed with a trench of the second substrate and operable to shield electromagnetic interference between MEMS components assembled with the second substrate.

15. The device of claim 5, wherein the first conductive structure is constructed from a multi-layer structure comprising: a magnetic layer positioned between a non-magnetic layer and an insulator layer.

16. The device of claim 15, wherein each of the multi-layer structure is constructed from the same metal.

17. An electromagnetic interference trench-based shielding system, comprising:
a substrate having one or more surfaces, the substrate being operable to receive one or more microelectromechanical system (MEMS) components;
one or more laminates operatively attached to the one or more surfaces of the first substrate;
a first conductive structure spanning a thickness defined by one or more of surfaces of the substrate, the first conductive structure in communication with a trench of the substrate and oriented generally orthogonal to the first substrate;
wherein the first conductive structure separates at least two MEMS components assembled to the substrate.

18. The system of claim 18, wherein the first conductive structure is integrally formed with the trench and extends a predetermined height away from the substrate.

19. A process of fabricating one or more electromagnetic shields between components for ultra-thin radiofrequency packages, the process comprising:
selectively inserting one or more through package vias (TPVs) in a substrate;
removing residue from an edge of the one or more TPVs by desmearing;
electroless seed plating the substrate thereby increasing thickness and conductivity;
coating the substrate by electrolytic plating with a metal;
thinning upper and lower surfaces of the substrate;
laminating upper and lower surfaces of the substrate with a first layer of photoresist film;
exposing the first layer of photoresist film of the upper and lower surfaces to wavelengths in the ultraviolet spectrum;
subtractive etching the electrolytic plating on the upper and lower surfaces of the substrate and stripping the photoresist film;
electroless seed layer plating on the upper and lower surfaces of the substrate;
applying a relatively a second layer of photoresist film to the upper surface of the substrate, the second layer being thicker than the first layer of photoresist film;
exposing the second layer of photoresist film to wavelengths in the ultraviolet spectrum;
electroplating the second layer of photoresist film with a metal;
stripping the relatively thick photoresist film and etching the electroless seed layer on the upper surface of the substrate thereby forming one or more electromagnetic interference (EMI) shields in communication with corresponding trenches of the substrate; and
laminating one or more layers to apply uniform pressure to uneven profiles of the substrate caused by the one or more EMI shields.

20. The method of claim 19, wherein the TPVs are selectively inserted using laser ablation and the substrate is electroless seed plated with copper.
